(19) United States
(12) Patent Application Publication
(10) Pub. No.: US 2025/0218858 A1
(43) Pub. Date: Jul. 3, 2025

(54) SAMPLE HOLDER

(71) Applicant: KYOCERA Corporation, Kyoto-shi, Kyoto (JP)

(72) Inventor: Musashi MORITA, Kagoshima-shi (JP)

(73) Assignee: KYOCERA Corporation, Kyoto-shi, Kyoto (JP)

(21) Appl. No.: 18/850,797

(22) PCT Filed: Mar. 17, 2023
(86) PCT No.: PCT/JP2023/010687

§ 371 Date: Sep. 25, 2024

(30) Foreign Application Priority Data
Mar. 29, 2022 (JP) 2022-054482

(51) Int. Cl. H01L 21/687; H01J 37/32

(52) U.S. Cl. CPC H01L 21/68785; H01J 37/32715; H01L 21/68757; H01J 2237/2007

(57) ABSTRACT

The sample holder includes a ceramic plate, a base member, and a fixing mechanism. The ceramic plate includes a first surface and a second surface opposite to the first surface. The base member includes a third surface located on the second surface of the ceramic plate and facing the second surface, a fourth surface located opposite to the third surface, and a through hole located at a position more inward than a peripheral edge of the ceramic plate and passing through the third surface and the fourth surface. The fixing mechanism is located corresponding to the through hole of the base member, and fixes the base member and the ceramic plate.

### CROSS-REFERENCE TO RELATED APPLICATIONS

This application is a national stage application of International Application No. PCT/JP2023/010687, filed on Mar. 17, 2023, which designates the United States, incorporated herein by reference, and which claims the benefit of priority from Japanese Patent Application No. 2022-054482, filed on Mar. 29, 2022, the entire contents of which are incorporated herein by reference.

### TECHNICAL FIELD

An embodiment of the disclosure relates to a sample holder.

### BACKGROUND OF INVENTION

There is a sample holder configured to hold a sample such as a semiconductor wafer to be plasma processed. Such a sample holder is configured by bonding a ceramic plate including a sample holding surface to a metal cooling member.

As a sample holder, a structure has been proposed in which a peripheral portion of a ceramic plate is fixed to a cooling member by clamps and bolts (see, for example, Patent Document 1).

### CITATION LIST

### Patent Literature

Patent Document 1: JP 2013-232642 A

### SUMMARY

A sample holder according to an aspect of an embodiment includes a ceramic plate, a base member, and a fixing mechanism. The ceramic plate includes a first surface and a second surface opposite to the first surface. The base member includes a third surface located on the second surface of the ceramic plate and facing the second surface, a fourth surface located opposite to the third surface, and a through hole located at a position more inward than a peripheral edge of the ceramic plate and passing through the third surface and the fourth surface. The fixing mechanism is located corresponding to the through hole of the base member, and fixes the base member and the ceramic plate.

### BRIEF DESCRIPTION OF THE DRAWINGS

FIG. 1 is a perspective view schematically illustrating a configuration of a sample holder according to an embodiment.

FIG. 2 is a cross-sectional view schematically illustrating the sample holder illustrated in FIG. 1.

FIG. 3 is a diagram illustrating an example of a layout of a fixing mechanism according to the embodiment.

FIG. 4 is a cross-sectional view schematically illustrating a sample holder according to another embodiment 1.

FIG. 5 is a cross-sectional view schematically illustrating a sample holder according to another embodiment 2.

FIG. 6 is a cross-sectional view schematically illustrating a sample holder according to another embodiment 3.

FIG. 7 is a cross-sectional view schematically illustrating a sample holder according to another embodiment 4.

FIG. 8 is a cross-sectional view schematically illustrating a sample holder according to another embodiment 5.

FIG. 9 is a cross-sectional view schematically illustrating a sample holder according to another embodiment 6.

FIG. 10 is a cross-sectional view schematically illustrating a sample holder according to another embodiment 7.

FIG. 11 is a cross-sectional view schematically illustrating a sample holder according to another embodiment 8.

FIG. 12 is a cross-sectional view schematically illustrating a sample holder according to another embodiment 9.

FIG. 13 is a cross-sectional view schematically illustrating a sample holder according to another embodiment 10.

FIG. 14 is a cross-sectional view schematically illustrating a sample holder according to another embodiment 11.

FIG. 15 is a cross-sectional view schematically illustrating a sample holder according to another embodiment 12.

FIG. 16 is a cross-sectional view schematically illustrating a sample holder according to another embodiment 13.

FIG. 17 is a cross-sectional view schematically illustrating a sample holder according to another embodiment 14.

FIG. 18 is a cross-sectional view schematically illustrating a sample holder according to another embodiment 15.

FIG. 19 is a cross-sectional view schematically illustrating a sample holder according to another embodiment 16.

### DESCRIPTION OF EMBODIMENTS

Hereinafter, an embodiment of a sample holder disclosed in the present disclosure will be described with reference to the accompanying drawings. The present disclosure is not limited by the following embodiments. Note that the drawings are schematic and that the dimensional relationships between elements, the proportions of the elements, and the like may differ from the actual ones. There may be differences between the drawings in terms of dimensional relationships, proportions, and the like.

In the embodiments described below, expressions such as “constant”, “orthogonal”, “perpendicular”, and “parallel” may be used, but these expressions do not mean exactly “constant”, “orthogonal”, “perpendicular”, and “parallel”. In other words, it is assumed that the above expressions allow for deviations in manufacturing accuracy, installation accuracy, or the like.

### Embodiments

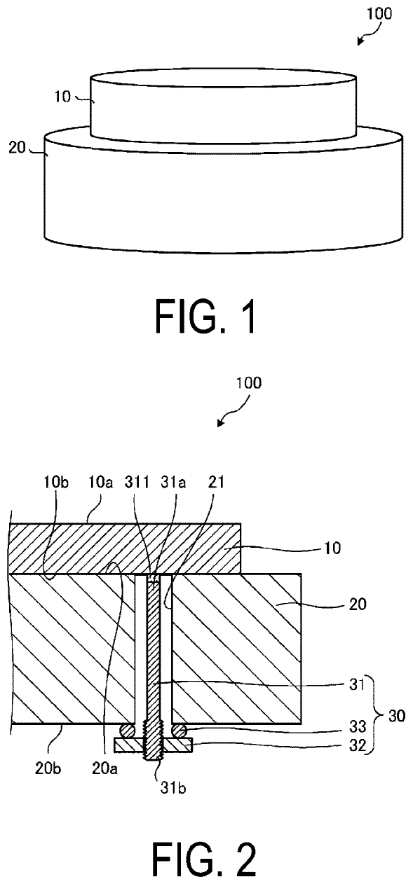

FIG. 1 is a perspective view schematically illustrating a configuration of a sample holder according to an embodiment. FIG. 2 is a cross-sectional view schematically illustrating the sample holder illustrated in FIG. 1.

As illustrated in FIGS. 1 and 2, a sample holder 100 includes a ceramic plate 10, a base member 20, and a fixing mechanism 30.

The ceramic plate 10 is a member obtained by molding a raw material containing ceramic into a substantially disk shape. The ceramic plate 10 adsorbs and holds a sample such as a semiconductor wafer by using an electrostatic force. The ceramic plate 10 contains, for example, aluminum oxide (Al₂O₃), aluminum nitride (AlN), yttria (Y₂O₃), or the like as a main component.

The ceramic plate 10 includes a first surface 10a and a second surface 10b on the opposite side to the first surface 10a. A sample such as a semiconductor wafer is held on the first surface 10a. That is, the first surface 10a serves as a sample holding surface for holding the sample.

An electrostatic adsorption electrode is located inside the ceramic plate 10. The ceramic plate 10 may include, for example, a heater electrode for heating the ceramic plate 10. As a material of these electrodes, for example, a metal such as platinum, tungsten, or molybdenum can be used.

The base member 20 is located on the second surface 10b side of the ceramic plate 10. The base member 20 is a support member that supports the ceramic plate 10. The base member 20 is attached to, for example, a semiconductor manufacturing device, and causes the sample holder 100 to function as a semiconductor holding device that holds a sample such as a semiconductor wafer.

The base member 20 is a substantially cylindrical member. The material of the base member 20 may be, for example, metal such as aluminum or stainless steel. In this case, the base member 20 may also serve as, for example, a high-frequency electrode.

The base member 20 functions as a cooling member that cools the ceramic plate 10 heated by a plasma treatment on the sample. The base member 20 may be, for example, a heat exchanger. In such a case, the base member 20 may have a flow path through which a liquid or gas heat exchange medium flows.

The base member 20 includes a third surface 20a which is a surface facing the second surface 10b, a fourth surface 20b which is located on the opposite side of the third surface 20a, and a through hole 21 which is located more inward than the peripheral edge of the ceramic plate 10 and penetrates the third surface 20a and the fourth surface 20b.

The fixing mechanism 30 is located corresponding to the through hole 21 of the base member 20. The fixing mechanism 30 fixes the base member 20 and the ceramic plate 10. Since the fixing mechanism 30 fixes the base member 20 and the ceramic plate 10 at the position of the through hole 21 of the base member 20, the base member 20 and the ceramic plate 10 can be brought into close contact with each other more inward than the peripheral edge of the ceramic plate 10. As a result, warp of the ceramic plate 10 caused by a difference in thermal expansion between the base member 20 and the ceramic plate 10 can be reduced as compared with the case where the peripheral edge portion of the ceramic plate is fixed to the base member (cooling member) by a clamp or the like as in the conventional sample holder. Therefore, the possibility that the thermal conductivity between the first surface 10a of the ceramic plate 10, that is, the sample holding surface and the base member 20 becomes non-uniform in the in-plane direction can be reduced, and as a result, the thermal uniformity in the plane of the sample holder 100 can be improved. Since the fixing mechanism 30 fixes the base member 20 and the ceramic plate 10 to each other without using a fixing material such as an adhesive, sliding between the ceramic plate 10 and the base member 20 is allowed, and a difference in expansion and contraction between the base member 20 and the ceramic plate 10 due to a thermal cycle is reduced.

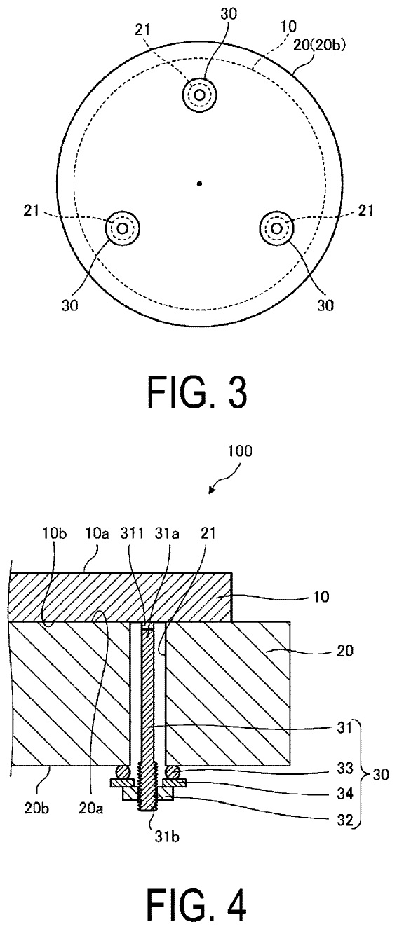

A plurality of fixing mechanisms 30 may be disposed on the base member 20. FIG. 3 is a diagram illustrating an example of a layout of a fixing mechanism according to the embodiment. FIG. 3 illustrates a view of the base member 20 viewed from a surface (that is, the fourth surface 20b) on the side opposite to the ceramic plate 10, and illustrates arrangement positions of the fixing mechanisms 30. The base member 20 includes the through holes 21 at a plurality of (here, three) positions more inward than the peripheral edge of the ceramic plate 10 at equal intervals along the peripheral edge of the ceramic plate 10. The fixing mechanisms 30 are located corresponding to the plurality of through holes 21, respectively. Since the plurality of fixing mechanisms 30 are disposed on the base member 20 in this manner, the base member 20 and the ceramic plate 10 can be fixed at a plurality of positions more inward than the peripheral edge of the ceramic plate 10. As a result, the possibility that the thermal conductivity between the first surface 10a of the ceramic plate 10, that is, the sample holding surface and the base member 20 becomes non-uniform in the in-plane direction can be reduced, and as a result, the thermal uniformity in the plane of the sample holder 100 can be further improved. Note that the arrangement positions of the fixing members 30 illustrated in FIG. 3 are merely an example and are not limited thereto. For example, the through hole 21 may be provided at a position corresponding to the center of the ceramic plate 10 of the base member 20, and the fixing mechanism 30 may be disposed at the position of the through hole 21. The through holes 21 may be provided at equal intervals on a plurality of concentric circles having different distances from the center of the ceramic plate 10, and the fixing mechanism 30 may be disposed at the position of each of the through holes 21. Four or more sets of the through holes 21 and the fixing mechanisms 30 may be provided, or only one set may be provided.

FIG. 1 and FIG. 2 will be described again. The fixing mechanism 30 includes a pillar-shaped member 31 and a fixing member 32.

One end portion 31a of the pillar-shaped member 31 is bonded to the second surface 10b of the ceramic plate 10 by a bonding material 311, and the pillar-shaped member 31 passes through the through hole 21. The pillar-shaped member 31 is made of metal. As the bonding material 311, for example, a brazing material containing silver, copper, or the like can be used. The other end portion 31b of the pillar-shaped member 31 protrudes from the through hole 21. Among side surfaces of the pillar-shaped member 31, at least the side surface of the end portion 31b is formed with a screw groove.

The fixing member 32 is located on the end portion 31b side of the pillar-shaped member 31. The material of the fixing member 32 is, for example, metal such as iron or stainless steel. The fixing member 32 presses the base member 20 toward the second surface 10b of the ceramic plate 10 to fix the base member 20 to the ceramic plate 10. This makes it possible to improve in-plane thermal uniformity of the sample holder 100. For example, the fixing member 32 is a nut including a screw hole in which a screw groove corresponding to the screw groove of the end portion 31b of the pillar-shaped member 31 is formed on the inner surface. The fixing member 32 is rotatably attached to the end portion 31b of the pillar-shaped member 31 by engaging the screw hole with the end portion 31b of the pillar-shaped member 31. The fixing member 32 moves in a direction approaching the base member 20 along the shaft of the pillar-shaped member 31 by rotation, and can generate a pressing force for pressing the base member 20 against the second surface 10b of the ceramic plate 10. With such a pressing force, the fixing member 32 can fix the base member 20 to the ceramic plate.

The fixing mechanism 30 further includes an elastic body 33. The elastic body 33 is located between the fixing member 32 and the base member 20. The fixing member 32 presses the base member 20 toward the second surface 10b of the ceramic plate 10 via the elastic body 33 to fix the base member 20 to the ceramic plate 10. The elastic body 33 may be an annular body having elasticity. In this case, the elastic body 33 may be, for example, an O-ring. Since the elastic body 33 is located between the fixing member 32 and the base member 20, the base member 20 and the ceramic plate 10 can be brought into close contact with each other more inward than the peripheral edge of the ceramic plate 10 by using the elastic force of the elastic body 33. That is, the fixing member 32 moves in a direction approaching the base member 20 along the shaft of the pillar-shaped member 31 by rotation, and can generate a pressing force for pressing the base member 20 against the second surface 10b of the ceramic plate 10 via the elastic body 33. This makes it possible to further improve in-plane thermal uniformity of the sample holder 100. Note that the elastic body 33 may be omitted as necessary.

### Other Embodiments

FIG. 4 is a cross-sectional view schematically illustrating a sample holder according to another embodiment 1. In the sample holder 100 illustrated in FIG. 4, the fixing mechanism 30 further includes a pressing plate 34.

The pressing plate 34 is located between the fixing member 32 and the elastic body 33. The pressing plate 34 is a substantially disc-shaped member including a hole formed in the center thereof through which the pillar-shaped member 31 can be inserted. The material of the pressing member 34 is, for example, metal such as iron or stainless steel. The pressing plate 34 is in contact with the fixing member 32 and the elastic body 33 in a state where the pillar-shaped member 31 is inserted through the pressing plate 34. The pressing plate 34 can press the elastic body 33 against the base member 20 in accordance with the pressing force from the fixing member 32. Since the pressing plate 34 is located between the fixing member 32 and the elastic body 33, the fixing member 32 does not come into direct contact with the elastic body 33. Therefore, the wear of the elastic body 33 can be reduced.

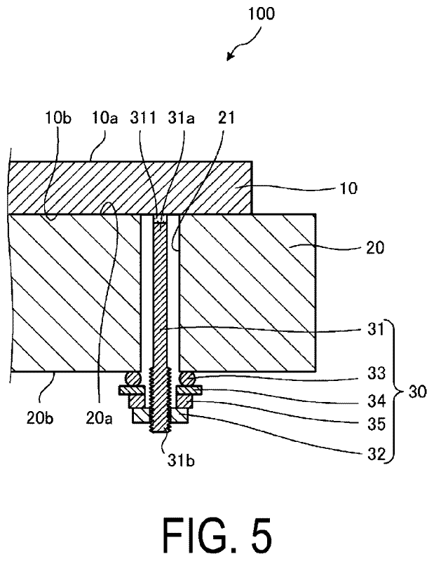

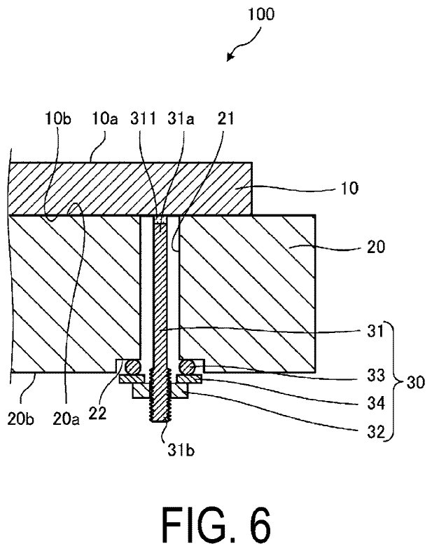

FIG. 5 is a cross-sectional view schematically illustrating a sample holder according to another embodiment 2. In the sample holder 100 illustrated in FIG. 5, the fixing mechanism 30 further includes a spring member 35.

The spring member 35 is located between the fixing member 32 and the pressing plate 34. The spring member 35 is a substantially disc-shaped member including a hole formed in the center thereof through which the pillar-shaped member 31 can be inserted, and has elasticity in the thickness direction. The spring member 35 may be, for example, a spring washer. The spring member 35 is elastically in contact with the fixing member 32 and the pressing plate 34 in a state where the pillar-shaped member 31 is inserted through the spring member 35. Since the spring member 35 is located between the fixing member 32 and the pressing plate 34, position shift of the elastic body 33 caused by looseness of the fixing member 32 can be reduced.

FIG. 6 is a cross-sectional view schematically illustrating a sample holder according to another embodiment 3. In the sample holder 100 illustrated in FIG. 6, the base member 20 includes a stepped portion 22 in a region including a position overlapping with the through hole 21 on the surface opposite to the ceramic plate 10. The stepped portion 22 has a diameter (width) larger than that of the through hole 21. The diameter (width) of the stepped portion 22 may be slightly larger than a diameter (width) of the elastic body 33. A depth of the stepped portion 22 may be smaller than a thickness of the elastic body 33. At least a part of the elastic body 33 is accommodated in this stepped portion 22. Since at least a part of the elastic body 33 is accommodated in the stepped portion 22, the position shift of the elastic body 33 can be reduced. This can reduce the deterioration of the adhesiveness between the base member 20 and the ceramic plate 10 caused by the position shift of the elastic body 33.

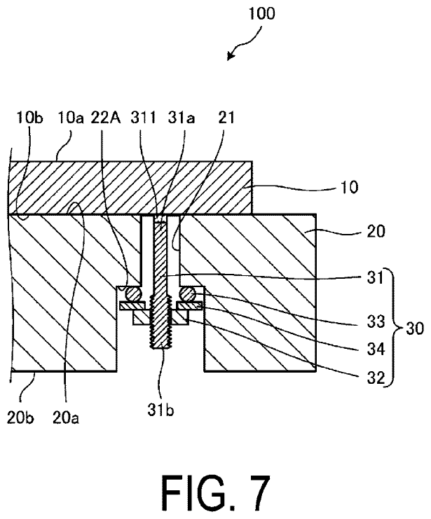

FIG. 7 is a cross-sectional view schematically illustrating a sample holder according to another embodiment 4. In the sample holder 100 illustrated in FIG. 7, the base member 20 includes a stepped portion 22A in a region including a position overlapping with the through hole 21 on the surface opposite to the ceramic plate 10. The stepped portion 22A has a diameter (width) larger than that of the through hole 21. The diameter (width) of the stepped portion 22A may be slightly larger than the diameter (width) of the elastic body 33. A depth of the stepped portion 22A may be larger than the thickness of the elastic body 33. The elastic body 33, the pressing plate 34, and the fixing member 32 are accommodated in this stepped portion 22A. In this case, the end portion 31b of the pillar-shaped member 31 may be located to recede from the surface of the base member 20 on the side opposite to the ceramic plate 10 in the depth direction of the stepped portion 22A. That is, the end portion 31b of the pillar-shaped member 31 may be located not to protrude from the surface of the base member 20 on the side opposite to the ceramic plate 10. As a result, heat transmitted from the ceramic plate 10 to the pillar-shaped member 31 can be released from the entire side surface of the pillar-shaped member 31 to the base member 20 via the stepped portion 22A and the inner wall surface of the through hole 21. As a result, deterioration of the elastic body 33 located at the stepped portion 22A can be reduced. Since no protrusion from the surface of the base member 20 on the side opposite to the ceramic plate 10 is present, convenience when the base member 20 is installed in, for example, a semiconductor manufacturing device is improved.

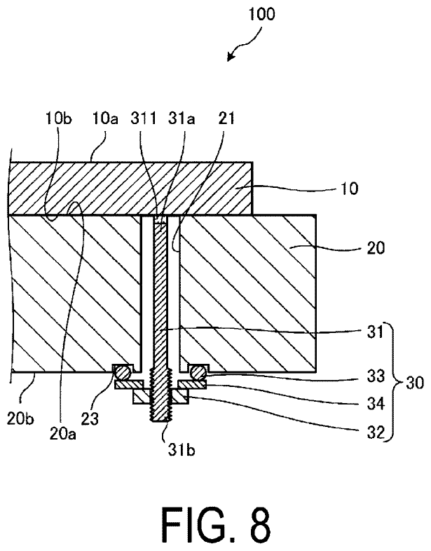

FIG. 8 is a cross-sectional view schematically illustrating a sample holder according to another embodiment 5. In the sample holder 100 illustrated in FIG. 8, the base member 20 includes a groove portion 23 in a region surrounding the through hole 21 on the surface opposite to the ceramic plate 10. For example, when the elastic body 33 is an annular body, the groove portion 23 may be formed in an annular shape corresponding to the shape of the elastic body 33. In this case, an inner diameter of the groove portion 23 may be slightly smaller than an inner diameter of the elastic body 33, and an outer diameter of the groove 23 may be slightly larger than an outer diameter of the elastic body 33. A depth of the groove portion 23 may be smaller than the thickness of the elastic body 33. At least a part of the elastic body 33 is accommodated in this groove portion 23. Since at least a part of the elastic body 33 is accommodated in the groove portion 23, the position shift of the elastic body 33 can be reduced. This can reduce the deterioration of the adhesiveness between the base member 20 and the ceramic plate 10 caused by the position shift of the elastic body 33.

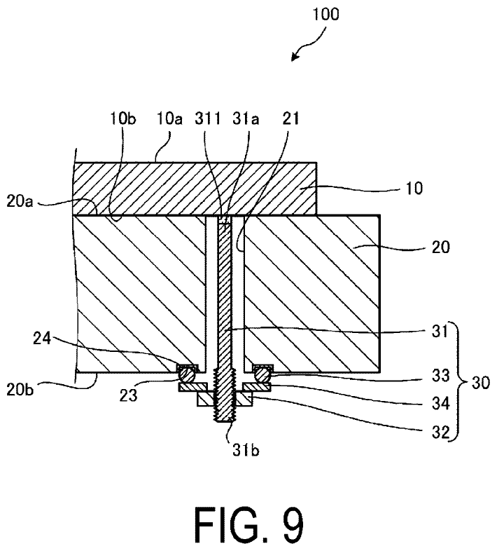

FIG. 9 is a cross-sectional view schematically illustrating a sample holder according to another embodiment 6. In the sample holder 100 illustrated in FIG. 9, the base member 20 includes a protecting member 24 having hardness lower than that of the base member 20 on an inner wall surface of the groove portion 23. As a material of the protecting member 24, for example, a resin having hardness lower than that of the base member 20 can be used. In this case, at least a part of the elastic body 33 is accommodated in the groove portion 23 via the protecting member 24. This can reduce wear of the elastic body 33 caused by friction with the base member 20.

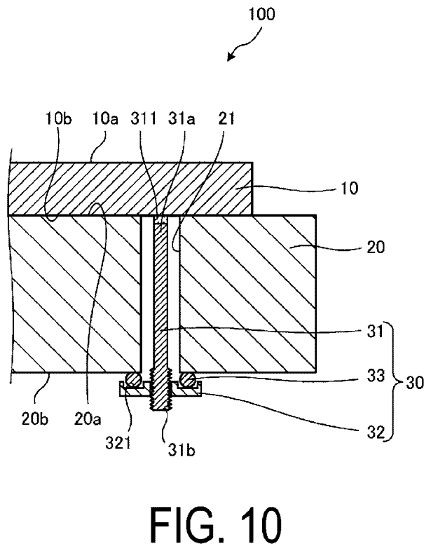

FIG. 10 is a cross-sectional view schematically illustrating a sample holder according to another embodiment 7. In the sample holder 100 illustrated in FIG. 10, the fixing member 32 includes a groove portion 321 in a region surrounding a position corresponding to the through hole 21 on the surface on the base member 20 side. For example, when the elastic body 33 is an annular body, the groove portion 321 may be formed in an annular shape corresponding to the shape of the elastic body 33. In this case, an inner diameter of the groove portion 321 may be slightly smaller than the inner diameter of the elastic body 33, and an outer diameter of the groove portion 321 may be slightly larger than the outer diameter of the elastic body 33. A depth of the groove portion 321 may be smaller than the thickness of the elastic body 33. At least a part of the elastic body 33 is accommodated in this groove portion 321. Since at least a part of the elastic body 33 is accommodated in the groove portion 321, the position shift of the elastic body 33 can be reduced.

This can reduce the deterioration of the adhesiveness between the base member 20 and the ceramic plate 10 caused by the position shift of the elastic body 33.

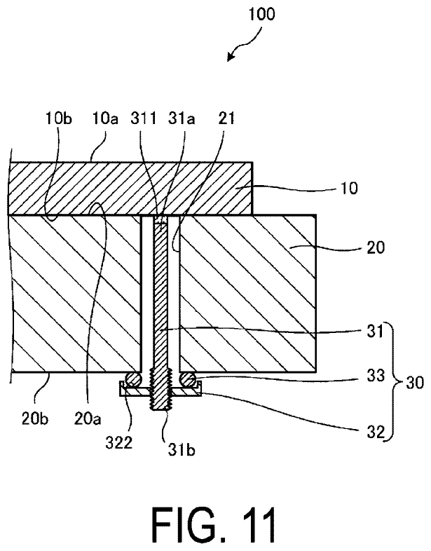

FIG. 11 is a cross-sectional view schematically illustrating a sample holder according to another embodiment 8. In the sample holder 100 illustrated in FIG. 11, the fixing member 32 includes a stepped portion 322 in a region including a position corresponding to the through hole 21 on the surface on the base member 20 side. The stepped portion 322 has a diameter (width) larger than that of the through hole 21. The diameter (width) of the stepped portion 322 may be slightly larger than the diameter (width) of the elastic body 33. A depth of the stepped portion 322 may be smaller than the thickness of the elastic body 33. At least a part of the elastic body 33 is accommodated in this stepped portion 322. Since at least a part of the elastic body 33 is accommodated in the stepped portion 322, the position shift of the elastic body 33 can be reduced. This can reduce the deterioration of the adhesiveness between the base member 20 and the ceramic plate 10 caused by the position shift of the elastic body 33.

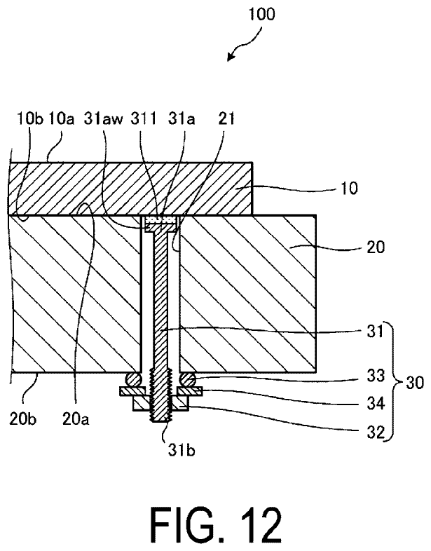

FIG. 12 is a cross-sectional view schematically illustrating a sample holder according to another embodiment 9. In the sample holder 100 illustrated in FIG. 12, the pillar-shaped member 31 includes a wide portion 31aw, which is wider than other portions, at the end portion 31a bonded to the second surface 10b of the ceramic plate 10. This increases the bonding strength between the second surface 10b of the ceramic plate 10 and the pillar-shaped member 31. Since the heat capacity of portions other than the wide portion 31aw of the pillar-shaped member 31 is smaller than the heat capacity of the wide portion 31aw, heat is less likely to be transmitted from the end portion 31a to the end portion 31b of the pillar-shaped member 31, and deterioration of the elastic body 33 located on the end portion 31b side can be reduced.

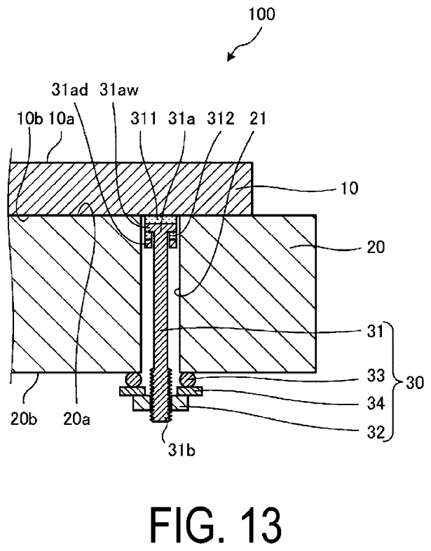

FIG. 13 is a cross-sectional view schematically illustrating a sample holder according to another embodiment 10. In the sample holder 100 illustrated in FIG. 13, the pillar-shaped member 31 includes a stress-dispersing member 31ad on the surface of the wide portion 31aw opposite to the ceramic plate 10. The stress-dispersing member 31ad may be a substantially ring-shaped member including a hole formed in the center thereof through which the pillar-shaped member 31 can be inserted. In this case, the stress-dispersing member 31ad is bonded to the surface of the wide portion 31aw opposite to the ceramic plate 10 with a bonding material 312 in a state where the pillar-shaped member 31 is inserted through the stress-dispersing member 31ad. As the bonding material 312, for example, a brazing material containing silver, copper, or the like can be used.

The stress-dispersing member 31ad is a member having a coefficient of thermal expansion closer to that of the ceramic plate 10 than the coefficient of thermal expansion of the pillar-shaped member 31. The material of the stress-dispersing member 31ad may be the same material as that of the ceramic plate 10. Since the stress-dispersing member 31ad is located on the surface of the wide portion 31aw opposite to the ceramic plate 10, the wide portion 31aw is restrained between the stress-dispersing member 31ad and the ceramic plate 10. Thus, the stress-dispersing member 31ad can disperse the stress caused by the difference in thermal expansion and contraction between the wide portion 31aw and the ceramic plate 10 to the stress-dispersing member 31ad and the ceramic plate 10. As a result, peeling of the wide portion 31aw from the second surface 10b of the ceramic plate 10 can be reduced.

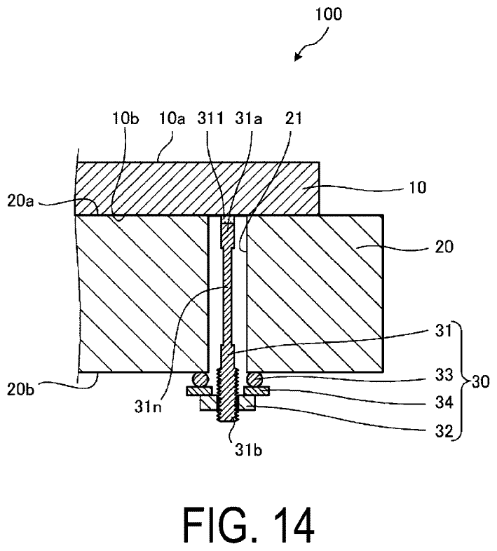

FIG. 14 is a cross-sectional view schematically illustrating a sample holder according to another embodiment 11. In the sample holder 100 illustrated in FIG. 14, the pillar-shaped member 31 includes a narrow portion 3 In that is narrower than the other portions. Accordingly, since the heat capacity of the narrow portion 3 In of the pillar-shaped member 31 is smaller than the heat capacity of the other portions other than the narrow portion 31n, heat is less likely to be transmitted from the end portion 31a to the end portion 31b of the pillar-shaped member 31, and deterioration of the elastic body 33 located on the end portion 31b side can be reduced.

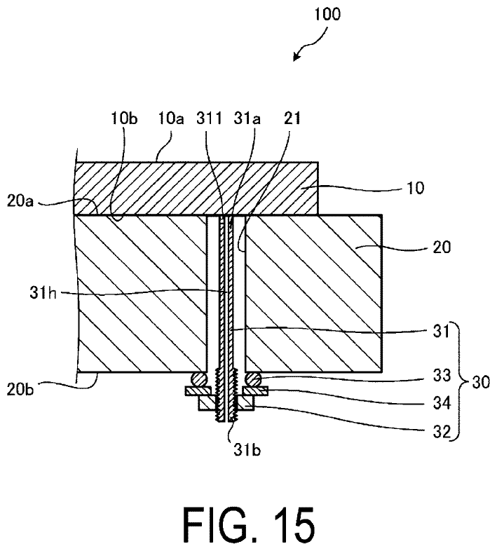

FIG. 15 is a cross-sectional view schematically illustrating a sample holder according to another embodiment 12. In the sample holder 100 illustrated in FIG. 15, the pillar-shaped member 31 includes therein a cavity portion 31h extending in an axial direction of the pillar-shaped member 31. The cavity portion 31h may be a through hole passing through the pillar-shaped member 31 in the axial direction. In this case, the cavity portion 31h may be, for example, a wiring hole or an electrode terminal hole through which an electrostatic adsorption electrode or a wire or an electrode terminal connected to the electrostatic adsorption electrode is inserted. Since the pillar-shaped member 31 includes the cavity portion 31h, a contact area between the pillar-shaped member 31 and the ceramic plate 10 is reduced and the heat capacity of the pillar-shaped member 31 is reduced. Accordingly, heat is less likely to be transmitted from the end portion 31a to the end portion 31b of the pillar-shaped member 31, and deterioration of the elastic body 33 located on the end portion 31b side can be reduced. Note that the cavity portion 31h may be used as a part of a purge gas hole or a lift pin hole.

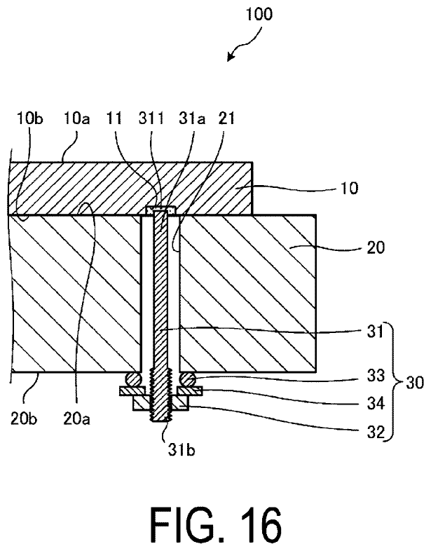

FIG. 16 is a cross-sectional view schematically illustrating a sample holder according to another embodiment 13. In the sample holder 100 illustrated in FIG. 16, the ceramic plate 10 includes a recessed portion 11 on the second surface 10b. The recessed portion 11 is wider than the end portion 31a of the pillar-shaped member 31. The end portion 31a of the pillar-shaped member 31 is located in the recessed portion 11. Since the end portion 31a of the pillar-shaped member 31 is in the recessed portion 11, the bonding strength between the second surface 10b of the ceramic plate 10 and the pillar-shaped member 31 is increased. Since the position shift of the pillar-shaped member 31 can be reduced, the deterioration of the adhesiveness between the base member 20 and the ceramic plate 10 caused by the position shift of the pillar-shaped member 31 can be reduced.

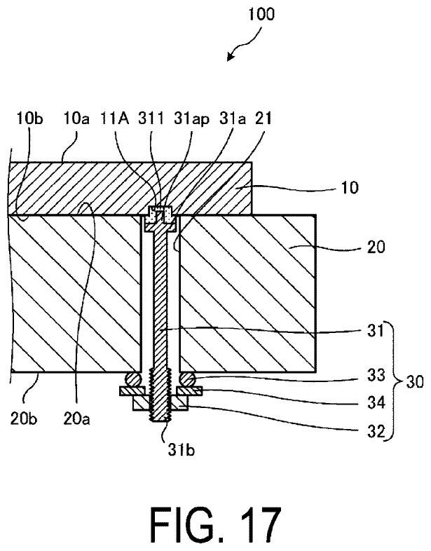

FIG. 17 is a cross-sectional view schematically illustrating a sample holder according to another embodiment 14. In the sample holder 100 illustrated in FIG. 17, the ceramic plate 10 includes a recessed portion 11A on the second surface 10b. The recessed portion 11A is narrower than the end portion 31a of the pillar-shaped member 31. The pillar-shaped member 31 includes a protruding portion 31ap protruding from an end surface of the end portion 31a. The protruding portion 31ap is located in the recessed portion 11A. Since the protruding portion 31ap is located in the recessed portion 11A, the bonding strength between the second surface 10b of the ceramic plate 10 and the pillar-shaped member 31 is increased. Since the position shift of the pillar-shaped member 31 can be reduced, the deterioration of the adhesiveness between the base member 20 and the ceramic plate 10 caused by the position shift of the pillar-shaped member 31 can be reduced.

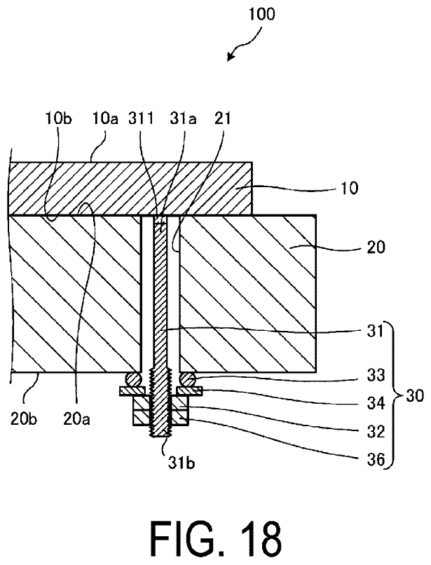

FIG. 18 is a cross-sectional view schematically illustrating a sample holder according to another embodiment 15. In the sample holder 100 illustrated in FIG. 18, the fixing mechanism 30 further includes another fixing member 36.

The fixing member 36 is located on the end portion 31b side of the pillar-shaped member 31. The material of the fixing member 36 is, for example, metal such as iron or stainless steel. The fixing member 36 is in contact with a surface of the fixing member 32 on a side opposite to the base member 20. The fixing member 36 presses the fixing member 32 toward the second surface 10b of the ceramic plate 10 to fix the position of the fixing member 32. For example, the fixing member 36 is a nut including a screw hole in which a screw groove corresponding to the screw groove of the end portion 31b of the pillar-shaped member 31 is formed on the inner surface. The fixing member 36 is rotatably mounted to the end portion 31b of the pillar-shaped member 31 by engaging the screw hole with the end portion 31b of the pillar-shaped member 31. The fixing member 36 can generate axial force between the fixing member 36 and the fixing member 32 by rotation. With such an axial force, the fixing member 36 can fix the position of the fixing member 32 and stop loosening of the fixing member 32. As a result, the deterioration of the adhesiveness between the base member 20 and the ceramic plate 10 due to loosening of the fixing member 32 can be decreased.

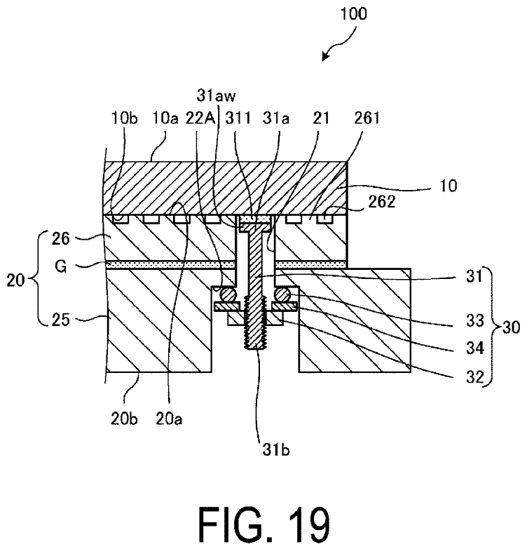

FIG. 19 is a cross-sectional view schematically illustrating a sample holder 100 according to another embodiment 16. As illustrated in FIG. 19, the base member 20 may include a cooling member 25, a heat-resistant member 26, and an adhesive G. The base member 20 including the cooling member 25, the heat-resistant member 26, and the adhesive G has a disc shape having a diameter larger than that of the ceramic plate 10 as a whole.

The cooling member 25 includes the fourth surface 20b. The cooling member 25 may be made of, for example, metal. As a metal material forming the base plate 25, for example, an aluminum matrix composite material such as aluminum, stainless steel, titanium, or AlSiC can be used. The metal cooling member 25 can cool the ceramic plate 10 heated by a heat generating resistor (not illustrated). The cooling member 25 may include an internal flow path through which a cooling medium such as cooling water or cooling gas flows. The cooling member 25 may be used as a high frequency electrode to which high frequency power for plasma generation is applied.

The heat-resistant member 26 includes the third surface 20a and is located between the ceramic plate 10 and the cooling member 25. The heat-resistant member 26 is formed of a material having a relatively low coefficient of thermal conductivity. The heat-resistant member 26 has a coefficient of thermal conductivity lower than that of the ceramic plate 10. As a material forming the heat-resistant member 26, for example, cordierite, glass, or the like can be used.

The adhesive G is located between the cooling member 25 and the heat-resistant member 26 and bonds the cooling member 25 and the heat-resistant member 26.

As described above, by providing the heat-resistant member 26 between the cooling member 25 and the ceramic plate 10, heat conduction from the ceramic plate 10 to the elastic body 33 via the base member 20 can be reduced.

Note that since the heat-resistant member 26 is interposed between the adhesive G and the ceramic plate 10, the influence of the heat generated by the ceramic plate 10 on the adhesive G is small as compared with the case where the adhesive is provided between the ceramic plate and the base member as in the related art. Therefore, the sample holder can withstand use in a high-temperature environment as compared with the conventional sample holder.

The heat-resistant member 26 includes a plurality of protruding portions 261 in contact with the ceramic plate 10 and spaces 262 located around the respective protruding portions 261 on the surface on the ceramic plate 10 side (that is, the third surface 20a). The plurality of protruding portions 261 and the spaces 262 can be formed by, for example, the surface of the heat-resistant member 26 on the ceramic plate 10 side (that is, the third surface 20a) being blasted. Since the heat-resistant member 26 includes the plurality of protruding portions 261 and the spaces 262, the contact surface area between the heat-resistant member 26 and the ceramic plate 10 can be reduced. As a result, the ceramic plate 10 easily slides with respect to the heat-resistant member 26. This can relax the stress generated by the expansion/contraction difference between the heat-resistant member 26 and the ceramic plate 10 due to the heat cycle.

The spaces 262 are located around the respective protruding portions 261 and between the ceramic plate 10 and the heat-resistant member 26. The space 262 has a depth corresponding to a height of each protruding portion 261. A heat transfer gas such as helium may be introduced into this space 262. That is, the space 262 may be a flow path of the heat transfer gas. By introducing the heat transfer gas into the space 262, the heat transfer gas can be fed to the second surface 10b of the ceramic plate 10, thus improving the heat transfer property between the heat-resistant member 26 and the ceramic plate 10 via the space 262.

A side surface of each protruding portion 261 may have a tapered shape in which the width decreases toward the ceramic plate 10. In other words, each protruding portion 261 may be formed in a tapered shape in which the width decreases toward the apex portion of each protruding portion 261. By forming each protruding portion 261 in a tapered shape, the surface area of the end surface of each protruding portion 261 in contact with the ceramic plate 10 can be reduced, and the contact surface area between the heat-resistant member 26 and the ceramic plate 10 can be reduced. As a result, the ceramic plate 10 more easily slides with respect to the heat-resistant member 26. This can further relax the stress generated by the expansion/contraction difference between the heat-resistant member 26 and the ceramic plate 10 due to the heat cycle.

A surface roughness Ra of the end surface of each protruding portion 261 in contact with the ceramic plate 10 may be smaller than a surface roughness Ra of the bottom surface of the space 262. Accordingly, the end surface of each protruding portion 261 and the ceramic plate 10 can be brought into uniform contact with each other in the in-plane direction, and heat transfer from the ceramic plate 10 to the plurality of protruding portions 261 can be equalized. When the surface roughness Ra of the end surface of each protruding portion 261 in contact with the ceramic plate 10 is small, the ceramic plate 10 more easily slides with respect to the heat-resistant member 26. This can further relax the stress generated by the expansion/contraction difference between the heat-resistant member 26 and the ceramic plate 10 due to the heat cycle. When the surface roughness Ra of the bottom surface of the space 262 is large, the surface area of the bottom surface of the space 262 can be increased. Thus, for example, when a heat transfer gas is introduced into the space 262, heat exchange between the heat transfer gas and the heat-resistant member 26 can be promoted.

Further effects and other embodiments can be readily derived by those skilled in the art. Thus, a wide variety of aspects of the present invention are not limited to the specific details and representative embodiments represented and described above. Accordingly, various changes can be made without departing from the spirit or scope of the general inventive concepts defined by the appended claims and their equivalents.

1. A sample holder comprising:
a ceramic plate;
a base member; and
a fixing mechanism,
wherein the ceramic plate comprises a first surface and a second surface opposite to the first surface,
the base member includes a third surface located on the second surface of the ceramic plate and facing the second surface, a fourth surface located opposite to the third surface, and a through hole located at a position more inward than a peripheral edge of the ceramic plate and passing through the third surface and the fourth surface, and
the fixing mechanism is located corresponding to the through hole of the base member, and fixes the base member and the ceramic plate.

2. The sample holder according to claim 1, wherein
the fixing mechanism comprises:
a pillar-shaped member; and
a fixing member,
the pillar-shaped member has one end bonded to the second surface of the ceramic plate and passes through the through hole, and
the fixing member is located on a side at which the other end of the pillar-shaped member is provided and presses the base member toward the second surface of the ceramic plate to fix the base member to the ceramic plate.

3. The sample holder according to claim 2, wherein
the fixing mechanism further comprises an elastic body located between the fixing member and the base member.

4. The sample holder according to claim 3, wherein
the fixing mechanism further comprises a pressing plate located between the fixing member and the elastic body.

5. The sample holder according to claim 4, wherein
the fixing mechanism further comprises a spring member located between the fixing member and the pressing plate, and elastically in contact with the fixing member and the pressing plate.

6. The sample holder according to claim 3, wherein
the base member comprises a stepped portion in a region comprising a position overlapping with the through hole on a surface opposite to the ceramic plate, and
at least a part of the elastic body is accommodated in the stepped portion.

7. The sample holder according to claim 3, wherein
the base member comprises a stepped portion in a region comprising a position overlapping with the through hole on a surface opposite to the ceramic plate,
the elastic body and the fixing member are accommodated in the stepped portion, and
the other end of the pillar-shaped member is located to recede in a depth direction of the stepped portion from the surface of the base member opposite to the ceramic plate.

8. The sample holder according to claim 3, wherein,
the base member comprises a groove portion in a region surrounding the through hole on a surface opposite to the ceramic plate, and
at least a part of the elastic body is accommodated in the groove portion.

9. The sample holder according to claim 8, wherein
the base member comprises a protecting member on an inner wall surface of the groove portion, the protecting member having a hardness lower than a hardness of the base member, and
at least a part of the elastic body is accommodated in the groove portion via the protecting member.

10. The sample holder according to claim 3, wherein,
the fixing member comprises a groove portion in a region surrounding a position corresponding to the through hole on a surface on a side of the base member, and
at least a part of the elastic body is accommodated in the groove portion.

11. The sample holder according to claim 3, wherein
the fixing member comprises a stepped portion in a region containing a position corresponding to the through hole on a surface on a side of the base member, and
at least a part of the elastic body is accommodated in the stepped portion.

12. The sample holder according to claim 2, wherein
the pillar-shaped member comprises a wide portion at the one end bonded to the second surface of the ceramic plate, the wide portion having a width larger than a width of other portions.

13. The sample holder according to claim 12, wherein
the pillar-shaped member comprises a stress-dispersing member on a surface of the wide portion opposite to the ceramic plate, the stress-dispersing member having a coefficient of thermal expansion closer to a coefficient of thermal expansion of the ceramic plate than a coefficient of thermal expansion of the pillar-shaped member.

14. The sample holder according to claim 2, wherein
the pillar-shaped member comprises a narrow portion having a width smaller than a width of another portion.

15. The sample holder according to claim 2, wherein
the pillar-shaped member comprises therein a cavity portion extending in an axial direction of the pillar-shaped member.

16. The sample holder according to claim 2, wherein
the ceramic plate comprises a recessed portion on the second surface, and
the one end of the pillar-shaped member is located in the recessed portion.

17. The sample holder according to claim 2, wherein
the ceramic plate comprises a recessed portion on the second surface,
the pillar-shaped member comprises a protruding portion protruding from an end surface of the one end, and
the protruding portion is located in the recessed portion.

18. The sample holder according to claim 2, wherein
the fixing mechanism further comprises another fixing member located on the other end side of the pillar-shaped member and in contact with a surface of the fixing member opposite to the base member.

19. The sample holder according to claim 1, wherein
the base member comprises the through holes at a plurality of positions more inward than a peripheral edge of the ceramic plate, and
the fixing mechanism is located corresponding to the through hole at each of the plurality of positions.

20. The sample holder according to claim 1, wherein
the base member comprises a heat-resistant member, a cooling member, and an adhesive bonding the heat-resistant member and the cooling member, and
the heat-resistant member comprises the third surface, and the cooling member comprises the fourth surface.
